(19) United States
(12) Patent Application Publication
(10) Pub. No.: US 2023/0377923 A1
(43) Pub. Date: Nov. 23, 2023

(54) INTEGRAL SEAL FOR CONTAINER

(71) Applicant: ENTEGRIS, INC., Billerica, MA (US)

(72) Inventors: William J. Shaner, Colorado Springs, CO (US); Matthew A. Fuller, Colorado Springs, CO (US); Michael C. Zabka, New Prague, MN (US); Alissa Wild, Chaska, MN (US)

(21) Appl. No.: 18/031,092

(22) PCT Filed: Oct. 13, 2021
(86) PCT No.: PCT/US2021/054667

§ 371 Date: Apr. 10, 2023

Related U.S. Application Data
(60) Provisional application No. 63/090,916, filed on Oct. 13, 2020.

(51) Int. Cl. H01L 21/673; G03F 1/66

(52) U.S. Cl. CPC H01L 21/67376; G03F 1/66

(57) ABSTRACT

An article includes a substrate container for holding one or more substrates or reticles. The substrate container has a housing including one or more sidewalls, a closed end, an open end, and an interior space defined by the one or more side walls and the closed end. The container further has a door configured to close the open end of the housing. The door includes a door body having a seal coupling portion. The door body is formed of a door body polymer. The door further includes a seal member integrally formed with the seal coupling portion of the door body.

### FIELD

This disclosure relates generally to containers for semiconductor substrates. More particularly, this disclosure relates to the door and door frame interface of such containers.

### BACKGROUND

Semiconductor substrates are commonly used during semiconductor fabrication. A semiconductor substrate undergoes a series of fabrication steps such as material layer deposition, doping, etching, etc. One or more semiconductor substrates can be held, carried, stored or transported in a container before, during, or after semiconductor fabrication.

Various containers are used to hold semiconductor substrates. It is desirable that substrate containers are sealed when the containers are closed and latched in position to keep the substrates clean, uncontaminated, and undamaged.

### SUMMARY

Some embodiments of an article include a substrate container for holding one or more substrates or reticles. The substrate container has a housing including one or more sidewalls, a closed end, an open end, and an interior space defined by the one or more side walls and the closed end. The container further has a door configured to close the open end of the housing. The door includes a door body having a seal coupling portion. The door body is formed of a door body polymer. The door further includes a seal member integrally formed with the seal coupling portion of the door body.

Other embodiments may include a method of making a door that closes an open end of a housing of a substrate or reticle container. The method includes insert molding a polymeric seal member on a periphery of a door body so that the polymeric seal member is integrally formed with the door body.

The details of one or more embodiments of the disclosure are set forth in the accompanying drawings and the description, and from the claims.

### BRIEF DESCRIPTION OF DRAWINGS

FIG. 1 is a front prospective view of a container for holding one or more semiconductor substrates.

FIG. 2 is a front view of the container of FIG. 1 when the container is in an open position.

FIG. 3 is a top view of an inner surface of a door of the container of FIG. 1.

FIG. 4 is a partial cross-sectional view of the container of FIG. 1 along IV-IV.

FIG. 5 is a partial cross-sectional view of a further embodiment of a container for holding one or more semiconductor substrates.

FIG. 6 is an exploded view of the seal member depicted in FIG. 5.

FIG. 7 is a partial cross-sectional view of a yet further embodiment of a container for holding one or more semiconductor substrates.

FIG. 8 is a partial cross-sectional view of a still further embodiment of a container for holding one or more semiconductor substrates.

FIG. 9 is flow chart showing a method of making a container door that includes an integrally formed seal member.

Like numbers represent like features.

### DETAILED DESCRIPTION

When used herein, the term “integral” or “integrally” means a door of a container is manufactured such that as components of the door, a seal member or a door body is formed into or around the opposing component. The term “integral” or “integrally” does not require that the materials for both a door body and the seal member be the same. When used herein, the term “interlock,” “interlocked” or “interlocking” refers to a mechanical coupling of two structural members that prevents separation of the two structural members without deforming at least one of the two structural members. When used herein, the term “join,” “joined” or “joining” means a seal member and a door body are in contact with each other when at least one of the two members is being formed. When used herein, the term “enlarged” means that a thickness of an edge is greater relative to the corresponding dimension of the portion of the object that is located farther away from the free end of the edge by substantially the same magnification factor.

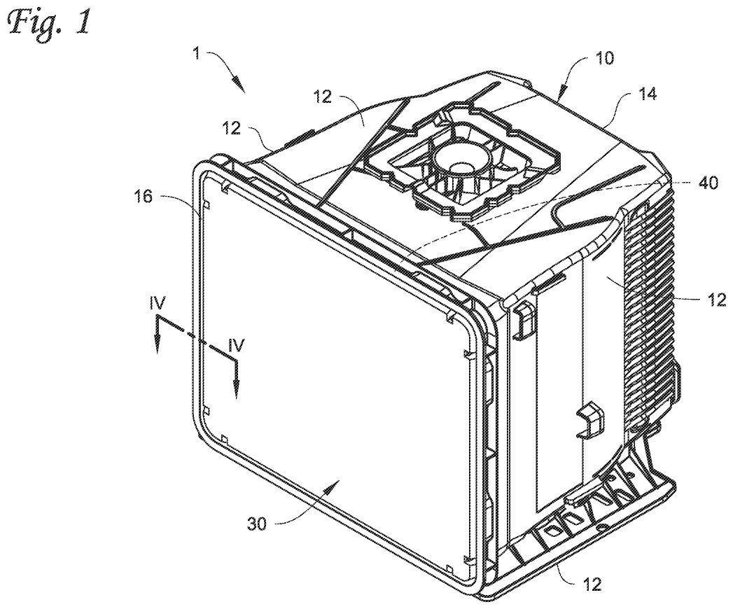

Referring to FIGS. 1-3, a substrate container 1 can be configured for holding, carrying, storing or transporting semiconductor substrates during semiconductor fabrication or other processes. Container 1 can include a housing 10 and a door 30 that can be secured to housing 10. Door 30 is formed with a seal member 40. Compared to a seal member that is inserted or otherwise assembled into a groove of the door by for example snap fit or press fit, which can be a source of particle generation, a door formed with an integral seal member can help prevent contamination caused by particles generated during this assembling process. In some embodiments, the integral seal concept can avoid unwanted fluids, such as a lubricating fluid used to reduce frictions during insertion of the seal member that can introduce contamination to the container. Additionally, the formation of the seal in accordance with this disclosure reduces or eliminates the generation of particles during the physical insertion of the seal into the door.

Referring to FIG. 1, container 1 can be used to hold one or more semiconductor substrates. Container 1 depicted in FIGS. 1-3 is one embodiment of a front opening unified pod (FOUP). In some embodiments, the container can be a semiconductor substrate shipping container. In other embodiments, the container can be a reticle pod. It is to be appreciated that the integral seal concept of this disclosure can be used with other types of containers.

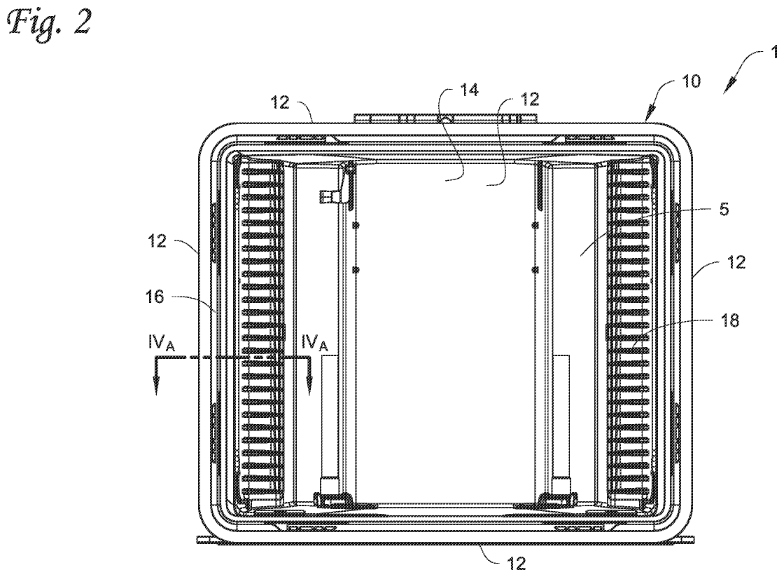

Referring to FIGS. 1 and 2, housing 10 has one or more sidewalls 12, a closed end 14, an open end 16 opposite the closed end 14 and an interior space 5 defined by side walls 12 and closed end 14. Door 30 is configured to couple to housing 10 and close open end 16.

In the embodiment depicted in FIGS. 1-3, door 30 is capable to engage with open end 16 of housing 10 to seal interior space 5. This can help prevent contamination of the semiconductor substrates held in the container by moisture, dust, etc. from outside environment. The one or more sidewalls 12 of housing 10 can be any number, and arrangement of side walls forms a continuous wall. Interior space 5 is defined by the one or more sidewalls 12 and closed end 14. Housing 10 further includes shelves 18 configured to hold semiconductor substrates. In some embodiments, container 1 may include one or more ports for selectively supplying one or more fluids into the interior space 5 of housing 10 or discharging fluids.

Referring to FIG. 1, door 30 is depicted in a closed position with a seal formed by the seal member 40 between housing 10 and door 30. In a front view of housing 10 depicted in FIG. 2, door 30 is removed and container 1 is in an open position where interior space 5 of housing 10 can be accessed.

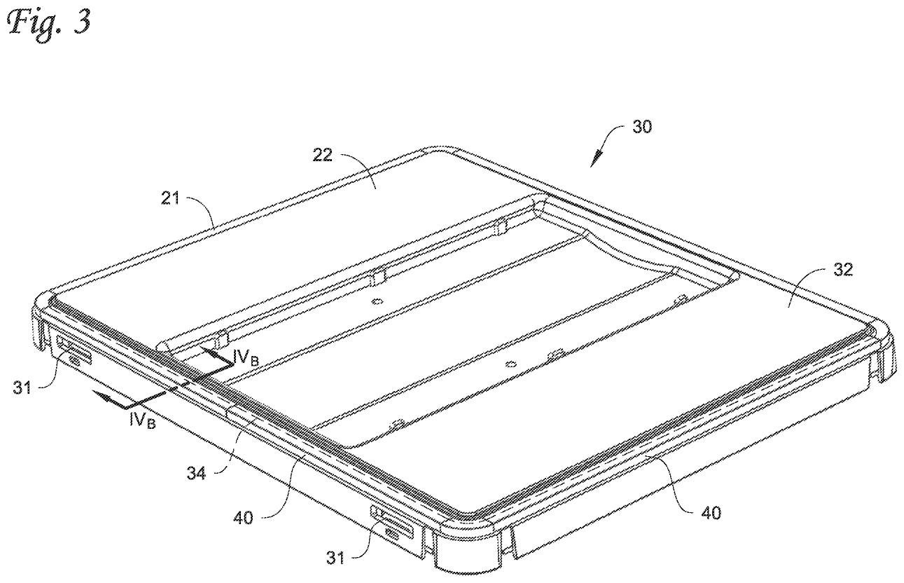

FIG. 3 shows a top perspective view of door 30. Door 30 includes a door body 32, an inner surface 22, the seal member 40 to seal open end 16 of housing 10, and a latch mechanism 31 to secure door 30 to housing 10. When door 30 is in a closed position as depicted in FIG. 1, inner surface 22 of door 30 is positioned to face the interior space 5.

Referring to FIG. 3, door body 32 has a seal coupling portion 34 at a periphery 21 of door body 32. Seal coupling portion 34 is formed integrally with seal member 40, thereby connecting seal member 40 with door body 32. It is to be appreciated that seal coupling portion 34 can be located at other locations on door body 32, instead of periphery 21. In some embodiments, door body 32 can be formed by injection molding.

In an embodiment, the door body 32 is made of a door body polymer. In an example, the door body polymer includes a thermoplastic polymer. In a further embodiment, the door body polymer includes one or more of polycarbonate, cyclic olefin, liquid crystal polymer, polypropylene, polyphenylene sulfide (PPS), polyphenylene sulfone (PPSU), polyetherimides, polyimide, polyamide imide, polyketone, polyether sulfone (PES), polybutylene terephthalate and polysulfone (PSU, PSF). In alternative embodiments, the door body polymer can include one or more of PolyAryl Ether Ketone Family polymers, such as polyaryl ether ketone (PAEK), polyether ether ketone (PEEK), polyether ketone ketone (PEKK) and polyether ketone ether ketone ketones (PEKEKK).

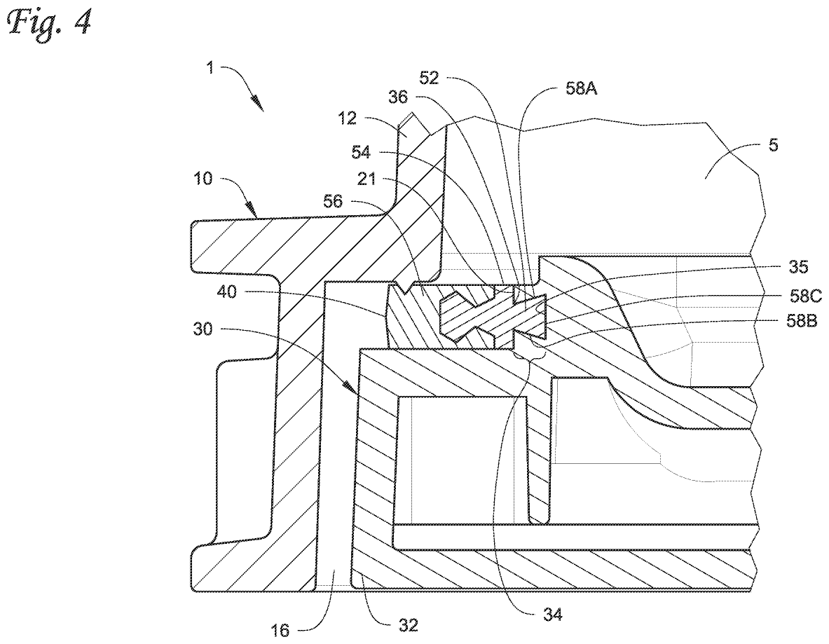

In the embodiment depicted in FIGS. 3 and 4, door body 32 also includes a seal coupling portion 34 of door body 32. In some embodiments, the seal coupling portion 34 extends along the entire circumference of door body 32.

Referring to FIG. 4, a partial cross-sectional view of container 1 taken along line IV-IV in FIG. 1 is shown. This partial cross-sectional view also shows a cross section of housing 10 taken along line IV_{A} in FIG. 2 and a cross section of door 30 taken along line IV_{B} in FIG. 3. Referring to FIG. 4, seal coupling portion 34 depicted in this embodiment includes a gap 36 and a channel 35. When viewed in a cross section view of this embodiment, a width of the gap 36 of the seal coupling portion is smaller than a width of the channel 35.

Referring to FIGS. 3 and 4, seal member 40 is integrally formed with seal coupling portion 34 of door body 32. It is to be appreciated that in an alternative embodiment, a seal member can be integrally formed on an edge of open end 16 of housing 10, instead of integrally formed with a door body. In such circumstances, the seal member formed on the housing 10 can be engaged with the door 30 to seal interior space 5.

Seal member 40 includes a connection portion 54 and a contact portion 56, and connection portion 54 can be formed with seal coupling portion 34 of door body 32 such that the two are interconnected to retain seal member 40 to door body 32. In some embodiments, connection portion 54 of seal member 40 is integrally formed into seal coupling portion 34 of door body 32. Referring to FIG. 4, in the depicted embodiment, the connection between seal member 40 and door body 32 is an interlocking connection that strengthens the integral connection between seal member 40 and door body 32. In this example, the connection portion 54 has an enlarged edge 52 secured to channel 35 of seal coupling portion 34 to form an interlocking connection, thereby preventing withdrawal of enlarged edge 52 from seal coupling portion 34 of door body 32. In one embodiment, the enlarged edge 52 takes a form of protrusion as shown in FIG. 4.

In some embodiments, connection portion 54 is made of a first polymer. The first polymer can be a different polymer than the door body polymer. In one example, the first polymer has hardness and stiffness greater than that of the material of contact portion 56, i.e., a second polymer as will be described in detail below. In another example, the first polymer is capable of withstanding any temperature suitable for the second polymer. In one embodiment, the first polymer is capable of withstanding a higher temperature compared with the one for the door body polymer. In one example, the first polymer can include one or both of polyether ether ketone and liquid crystal polymer.

In some embodiments, the first polymer has a compressibility configured to prevent the enlarged edge 52 of seal member 40 from being compressed to a size equal to or smaller than a width of gap 36 of seal coupling portion 34 of door body 32 so as to form an interlocking connection.

Seal member 40 and door body 32 can be connected to each other by various methods as desired. In some embodiments, seal member 40 or door body 32 can be formed integrally into or around the opposing component by various molding processes. In one embodiment, seal member 40 can be formed into a portion of door body 32, such as seal coupling portion 34 of door body 32. In another embodiment, seal member 40 can be formed around a portion of door body 32. For example, the seal member 40 can be formed around seal coupling portion 34 of door body 32.

In some embodiments, seal member 40 is formed integrally with door body 32 by injection molding. In one embodiment, the process includes insert molding seal member with door body 32. Insert molding can include disposing part of connection portion 54 of seal member 40 within a mold cavity, selectively covering the mold cavity with a cover, and injecting polymer through an injection channel into the mold cavity such that door body polymer forms around part of connection portion 54 to form an integral connection, thereby preventing disengagement of connection portion 54 from seal coupling portion 34 of door body 32.

Referring to FIG. 4, after insert molding, connection portion 54 of seal member is joined to and formed around by a portion of door body 32, and seal coupling portion 34 is now formed and integrally connected to the connection portion 54 of seal member 40. In the embodiment depicted in FIG. 4, connection portion 54 of seal member 40 has an enlarged edge 52. The enlarged edge 52 is held in seal coupling portion 34 of door body 32 to form an interlocking connection, thereby further strengthening the integral connection between seal member 40 and door body 32. This allows seal member 40 to be formed on door body 32 without the need of physically inserting a seal member into channel 35 of seal coupling portion 34. As a result, this helps minimize the chance of particle generation, solution contamination or leakage pathways.

Still referring to FIG. 4, in the embodiment depicted, when viewed in a cross section view, the enlarged edge 52 includes at least two sides 58A, 58B, and a distal end 58C. The distal end 58C is located farthermost away from contact portion 56. In an example, channel 35 of seal coupling portion 34 fits about both sides 58A, 58B and the end 58C of the enlarged edge 52. In the depicted embodiment, the enlarged edge 52 has a tapered shape when extending from the distal end 58C toward contact portion 56. It is to be appreciated that the specific shape of enlarged edge 52 of connection portion 54 can vary. In fact, the enlarged edge 52 can take any form as long as it can cooperate with channel 35 of seal coupling portion 34 to form an interlocking connection and hold seal member 40 in place.

It is to be appreciated that the connection formed between seal member 40 and door body 32 can take forms other than the seal coupling portion and enlarged edge cooperation.

When door 30 is in the closed position, seal member 40 is configured to form a seal between door body 32 and housing 10 to seal interior space 5. For example, in the embodiment depicted in FIGS. 3-4, seal member 40 contacts each of sidewalls 12 of housing 10, such that a seal is formed between each of sidewalls 12 and door body 32. In the embodiment depicted in the figures, seal member 40 is a continuous seal member formed around the periphery of door body 32. It is to be appreciated that the seal member can include multiple structural members as desired.

Referring to FIG. 4, contact portion 56 of seal member 40 is configured to seal the open end 16 of housing 10, when door 30 is in a closed position. In such circumstances, contact portion 56 has an outer surface that is configured to contact housing 10 directly.

It is to be understood that in some embodiments, seal member 40 can be integrally formed around seal coupling portion 34 of door body 32. For example, instead of being formed into door body 32, connection portion 54 of seal member 40 can be formed around an outer surface of seal coupling portion 34 of door body 32 such that seal member 40 and door body 32 are integrally connected with each other.

In some embodiments, contact portion 56 includes a second polymer that is different from the door body polymer. In one embodiment, the second polymer includes an elastomeric polymer. In another embodiment, the second polymer incudes a thermoplastic elastomer. In a further embodiment, the second polymer includes a thermoset elastomer, such as fluoropolymer.

In some embodiments, the second polymer includes a polymer that has a shore durometer not less than 30 shore. In other embodiments, the second polymer is capable of withstanding a temperature of 130° C. In one embodiment, the second polymer includes polypropylene. In some embodiments, the second polymer includes at least one of fluoropolymer, fluoroelastomer (FKM), perfluoro elastomer (FFKM), styrenic block copolymer (SBC), polyether-ester block copolymer (COPE), thermoplastic olefin (TPO), thermoplastic vulcanizate (TPV), thermoplastic polyuerethane (TPU) and copolyamide elastomer (COPA).

In some embodiments, contact portion 56 is made of a different material from that of connection portion 54. In one embodiment, the first polymer of connection portion 54 has a higher rigidity than the second polymer of contact portion 56. In an embodiment, at least 50 wt % of the second polymer is an elastomeric polymer, such as fluoropolymer or polyether ether ketone.

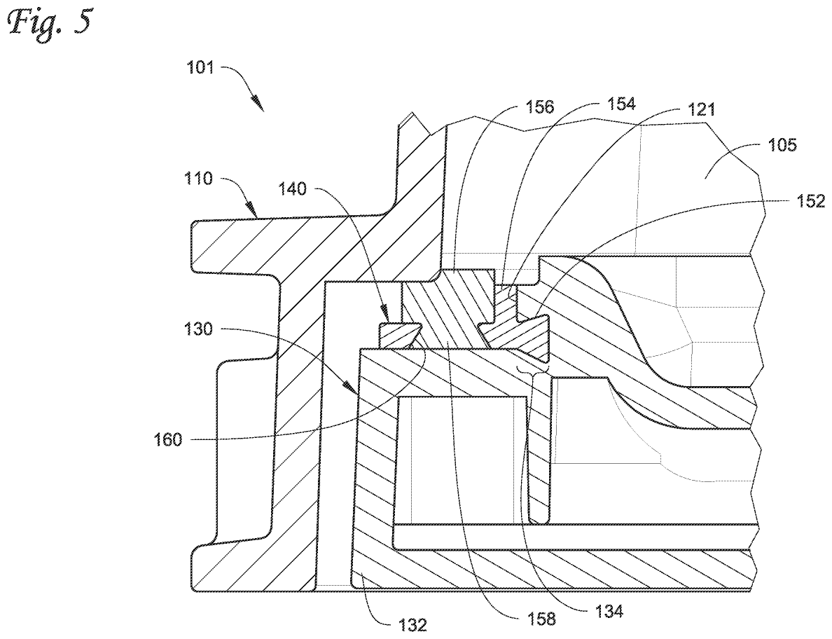

Referring to FIG. 5, in a partial cross-sectional view of a further embodiment, a container 101 similar to the embodiment discussed above with respect to FIGS. 1-4 is depicted, with a different configuration for a seal member. The cross-sectional view in FIG. 5 is taken along a similar plane of container 101 as described with respect to the cross-sectional view for FIG. 4. The container 101 has a housing 110 with an interior space 105 and a door 130 with an integral seal member 140. Door 130 has a door body 132. Door body 132 has a seal coupling portion 134 at a periphery 121 of door body 132. Seal member 140 is integrally formed with seal coupling portion 134. In the depicted embodiment, seal member 140 has a contact portion 156 extending through a connection portion 154 in a cross sectional view, while connection portion 154 has an enlarged edge 152 formed into the seal coupling portion 134 of door body 132.

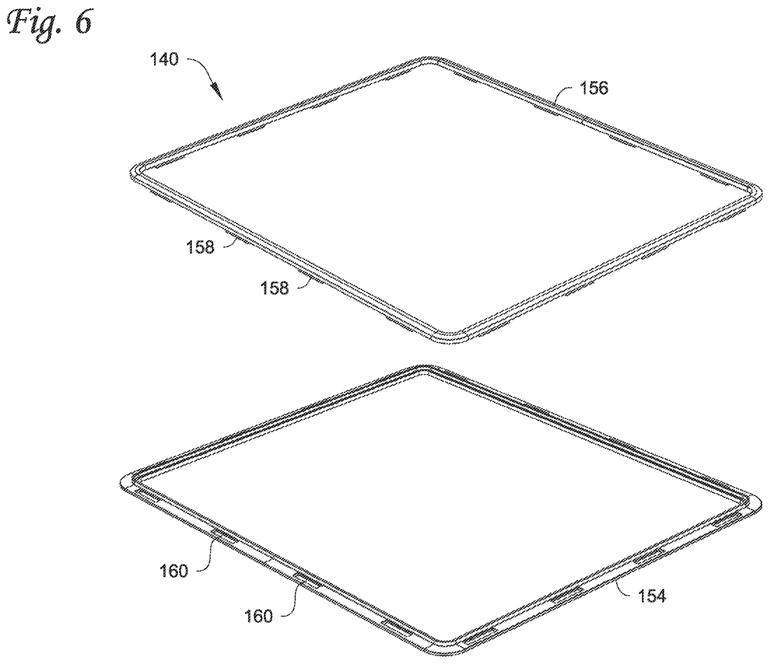

FIG. 6 depicts an exploded view of seal member 140 of FIG. 5. As shown in FIGS. 5 and 6, connection portion 154 is a rectangular structural member corresponding to the shape of the periphery 121 of door body 132. Connection portion 154 includes openings 160. Contact portion 156 has a shape corresponding to that of the connection portion 154, and contact portion 156 includes tabs 158. To assemble connection portion 154 and contact portion 156 to each other, tabs 158 of contact portion 156 are extended through respective openings 160 on connection portion 154. In such circumstances, connection portion 154 and contact portion 156 are secured to each other. It is to be appreciated that the specific shape of the connection portion and the specific shape of the contact portion can vary, as long as the seal member formed by the connection portion and the contact portion is capable of sealing the substrate container.

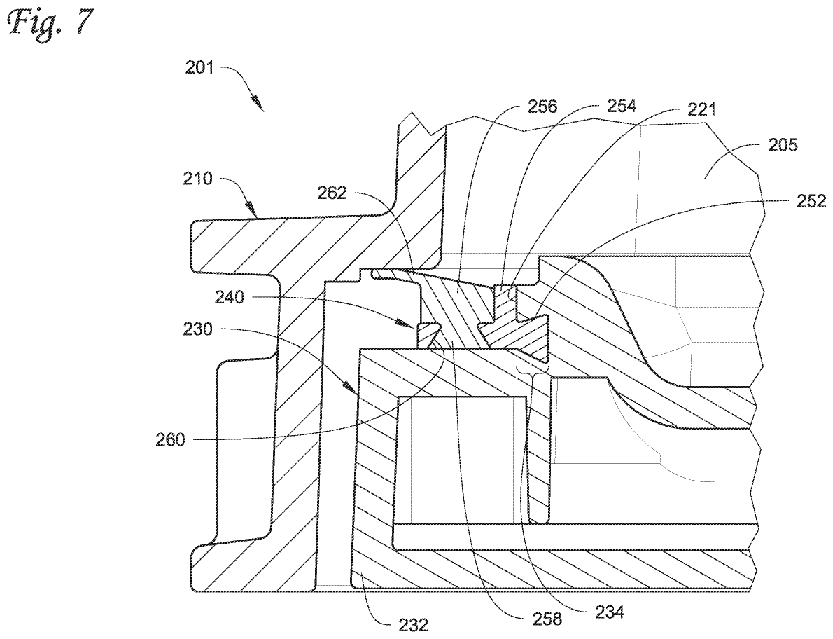

Referring to FIG. 7, in a partial cross-sectional view of a yet further embodiment, a container 201 similar to the embodiment discussed above with respect to FIGS. 5-6 is depicted, with a different configuration for a seal member. The cross-sectional view in FIG. 7 is taken along a similar plane of container 201 as described with respect to the cross-sectional view for FIG. 4. The container 201 has a housing 210 with an interior space 205 and a door 230 with an integral seal member 240. Door 230 has a door body 232. Door body 232 has a seal coupling portion 234 at a periphery 221 of door body 232. Seal member 240 is integrally formed with seal coupling portion 234. In the depicted embodiment, seal member 240 has a contact portion 256 extending through a connection portion 254 in a cross sectional view, while connection portion 254 has an enlarged edge 252 formed into the seal coupling portion 234 of door body 232. Similar to the configuration of seal member 140 in FIGS. 5 and 6, connection portion 254 includes openings 260, and contact portion 256 includes tabs 258 extending through respective openings 260 on connection portion 254. In such circumstances, connection portion 254 and contact portion 256 are secured to each other.

Still referring to FIG. 7, in this embodiment, contact portion 256 of seal member 240 further includes a wiper-type gasket 262 projecting outwardly from contact portion 256 of seal member 240 and extending along a surface of housing 210 to seal the interface between door 230 and housing 210 and shieldingly protect interior space of housing 210.

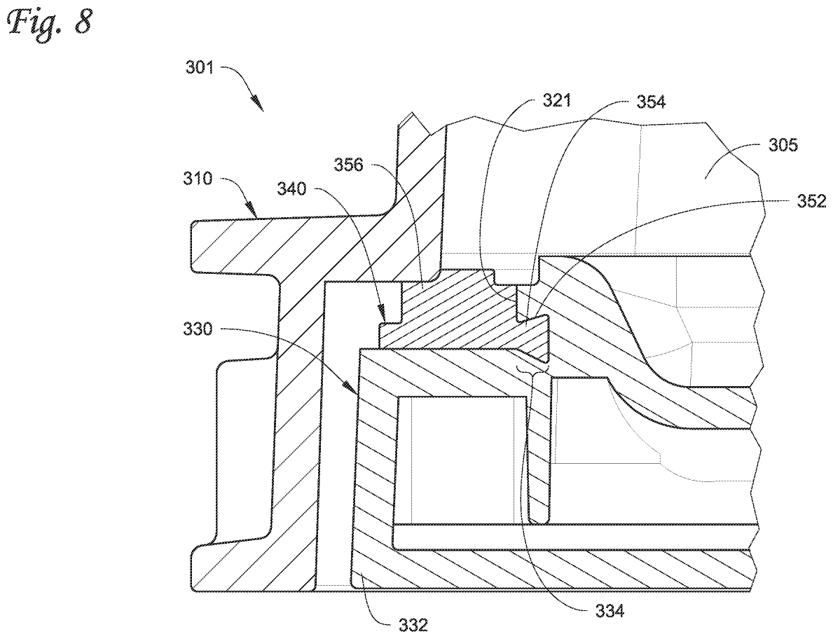

Referring to FIG. 8, in a partial cross-sectional view of a still further embodiment, a container 301 similar to the embodiment discussed above with respect to FIGS. 1-4 is depicted, with a different configuration for a seal member. The cross-sectional view in FIG. 8 is taken along a similar plane of container 301 as described with respect to the cross-sectional view for FIG. 4. The container 301 has a housing 310 with an interior space 305 and a door 330 with an integral seal member 340. Door 330 has a door body 332. Door body 332 has a seal coupling portion 334 at a periphery 321 of door body 332. Seal member 340 is integrally formed with seal coupling portion 334. In the depicted embodiment, seal member 340 has an enlarged edge 352 formed into the seal coupling portion 334 of door body 332.

Still referring to FIG. 8, in this embodiment, while seal member 340 includes a connection portion 354 and a contact portion 356 these two portions 354, 356 are part of one uniform body made of the same material. For example, seal member 340 may be made of the same material including one or more polymers, additives, etc. In some embodiments, seal member 340 is made of one or more gasket materials, such as fluroelastomer (FKM).

Various methods can be used to make a door of a substrate container that has a door body and an integral seal member. In some embodiments, the seal member can be formed into or around a portion of the door body by various molding processes. In one embodiment, a seal member can be formed into a seal coupling portion of a door body. In another embodiment, a seal member can be formed around an outer surface of a seal coupling portion of a door body.

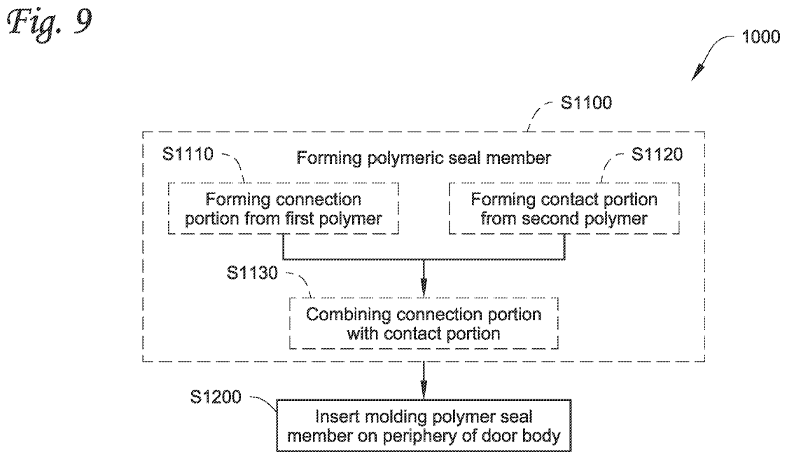

Referring to FIG. 9, a flow diagram for a method 1000 of forming a container door integrally with a polymeric seal member is depicted. For example, the method 1000 may be used to form door 30 in FIGS. 1-4, door 130 in FIG. 5, door 230 in FIG. 7 or door 330 in FIG. 8. Starting at S1100, form a polymeric seal member of the container door. In some embodiments, the polymeric seal member has one structural member including a connection portion and a contact portion as part of the same uniform body.

In other embodiments, the polymeric seal member includes a connection portion and a contact portion distinct from each other. In such a circumstance, forming a polymeric seal member includes forming a connection portion at S1110 and forming a contact portion S1120. In an example, the connection portion is made of a first polymer, and the contact portion is made of a second polymer. At S1130, combine the connection portion and the contact portion to each other.

At S1200, insert mold the polymeric seal member with the container door, including disposing a connection portion of the seal member within a mold cavity, selectively covering the mold cavity with a cover, and injecting polymer through an injection channel into the mold cavity such that a door body polymer forms around at least partially the connection portion of the polymeric seal member. In such circumstances, the polymeric seal member is integrally formed with the container door.

In some embodiments, the polymeric seal member can be treated by various surface treatments to impart different surface properties as needed. For example, the polymeric seal member can be prepared by desired surface treatment, such as plasma or corona treatment, before insert molding the polymeric seal member with the container door. In other embodiments, the polymeric seal member can be pre-treated with bonding agents to improve bonding strength between the polymeric seal member and the door body.

In some embodiments, a door is made by inserting a seal member into a channel of a seal coupling portion formed at a periphery of a door body. In an alternative embodiment, a seal member is formed into a door body without the need of physically inserting the seal member into a channel of a seal coupling portion of the door body. Instead, the seal member is integrally formed into or around a seal coupling portion of the door body by, for example, a molding process.

It is to be appreciated that in an alternative embodiment, the polymer seal member can be integrally formed on the door body by forming the connection portion of the polymeric seal member around a periphery of the door body.

### ASPECTS

Any of aspects 1-25 can be combined with any of aspects 26-29.

Aspect 1. An article comprising:
a substrate container for holding one or more substrates or reticles, the substrate container having:
a housing including one or more sidewalls, a closed end, an open end, and an interior space defined by the one or more side walls and the closed end; and
a door configured to close the open end of the housing, the door including:
   a door body having a seal coupling portion, the door body being formed of a door body polymer, and
   a seal member integrally formed with the seal coupling portion of the door body.

Aspect 2. The container of aspect 1, wherein the seal member includes a connection portion and a contact portion, the connection portion being formed with the seal coupling portion of the door body such that the connection portion and the seal coupling portion of the door body are connected with each other, the contact portion being configured to seal the open end when the door is in a closed position.

Aspect 3. The container of any of aspects 1-2, wherein the door body polymer includes a thermoplastic.

Aspect 4. The container of any of aspects 1-3, wherein the door body polymer includes at least one material selected from the group consisting of polycarbonate, cyclic olefin, liquid crystal polymer, polypropylene, polyphenylene sulfide (PPS), polyphenylene sulfone (PPSU), polyetherimides, polyimide, polyamide imide, polyketone, polyether sulfone (PES), polybutylene terephthalate, polysulfone (PSU, PSF), polyaryl ether ketone (PAEK), polyether ether ketone (PEEK), polyether ketone (PEKK) and polyether ketone ether ketone ketones (PEKEKK).

Aspect 5. The container of any of aspects 1-4, wherein the seal member is formed integrally with the door body by injection molding.

Aspect 6. The container of any of aspects 2-4, wherein the connection portion interlocks with the seal coupling portion of the door body.

Aspect 7. The container of aspect 6, wherein the connection portion of the seal member has an enlarged edge, the enlarged edge being configured to held by the seal coupling portion of the door body to form an interlocking connection, thereby preventing withdrawal of the connection portion from the seal coupling portion of the door body.

Aspect 8. The container of aspect 7, wherein the seal coupling portion includes a gap and a channel; when viewed in a cross section view, a width of gap of the seal coupling portion being smaller than a width of the channel.

Aspect 9. The container of aspect 8, wherein the connection portion includes a first polymer, the first polymer having a compressibility configured to prevent the enlarged edge of the connection portion from being compressed to a size equal to or smaller than the gap of the seal coupling portion formed into the door body so as to form the interlocking connection.

Aspect 10. The container of any of aspects 7-9, wherein the enlarged edge of the connection portion of the seal member is joined to and formed around by the seal coupling portion of the door body.

Aspect 11. The container of any of aspects 2-11, wherein the contact portion includes a wiper-type gasket.

Aspect 12. The container of any of aspects 2-11, wherein the connection portion is made of a first polymer different from the door body polymer.

Aspect 13. The container of aspect 12, wherein the first polymer includes polyether ether ketone, liquid crystal polymer, or a combination thereof.

Aspect 14. The container of any of aspects 12-13, wherein the contact portion is made of a second polymer different from the first polymer and the door body polymer.

Aspect 15. The container of aspect 14, wherein the second polymer includes an elastomeric polymer.

Aspect 16. The container of any of aspects 14-15, wherein the second polymer includes a thermoset or a thermoplastic elastomer.

Aspect 17. The container of any of aspects 14-16, wherein the second polymer includes a polymer that has a shore durometer not less than 30 shore.

Aspect 18. The container of any of aspects 14-17, wherein the second polymer is capable of withstanding a temperature of 130° C.

Aspect 19. The container of any of aspects 14-18, wherein the second polymer includes at least one material selected from the group consisting of fluoropolymer, fluoroelastomer (FKM), perfluoro elastomer (FKKM), styrenic block copolymer (SBC), polyether-ester block copolymer (COPE), thermoplastic olefin (TPO), thermoplastic vulcanizate (TPV), thermoplastic polyuerethane (TPU) and copolyamide elastomer (COPA).

Aspect 20. The container of any of aspects 14-19, wherein the first polymer has hardness and stiffness that are greater than those of the second polymer

Aspect 21. The container of any of aspects 14-20, wherein the first polymer is capable of withstanding any temperature for the second polymer.

Aspect 22. The container of any of aspects 2-21, wherein the connection portion and the contact portion are made of the same polymer.

Aspect 23. The container of any of aspects 1-22, wherein the container is one of a front opening unified pod, a reticle pod, and a semiconductor substrates shipping container.

Aspect 24. The container of any of aspects 1-23, wherein the seal coupling portion is located at a periphery of the door body.

Aspect 25. The container of any of aspects 1-24, wherein the seal coupling portion extends along an entire circumference of the periphery of the door body.

Aspect 26. A method of making a door that closes an open end of a housing of a substrate or reticle container, comprising:

insert molding a polymeric seal member on a seal coupling portion of a door body so that the polymeric seal member is integrally formed with the door body.

Aspect 27. The method of aspect 26, wherein the polymeric seal member is joined to and formed into a seal coupling portion of a door body of the door so that the polymeric seal member and the periphery of the door body are connected with each other.

Aspect 28. The method of any of aspects 26-27, further comprising:
forming the seal member, including:
   forming a connection portion of the polymeric seal member from a first polymer different from the door body polymer, the connection portion including an enlarged edge sized to be formed into the seal coupling portion of the door body; and
   forming a contact portion of the polymeric seal member from a second polymer different from the door body polymer and the first polymer, the contact portion being configured to seal the open end of the housing of the container when the door is in a closed position.

Aspect 29. The method of any of aspects 26-28, wherein insert molding the polymeric seal member on the seal coupling portion of the door body includes forming a door body polymer around a connection portion of the polymeric seal member within an insert mold.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

What is claimed is:

1. An article comprising:
a substrate container for holding one or more substrates or reticles, the substrate container having:
a housing including one or more sidewalls, a closed end, an open end, and an interior space defined by the one or more side walls and the closed end; and
a door configured to close the open end of the housing, the door including:
a door body having a seal coupling portion, the door body being formed of a door body polymer, and
a seal member integrally formed with the seal coupling portion of the door body.

2. The container of claim 1, wherein the seal member includes a connection portion and a contact portion, the connection portion being formed with the seal coupling portion of the door body such that the connection portion and the seal coupling portion of the door body are connected with each other, the contact portion being configured to seal the open end when the door is in a closed position.

3. The container of claim 1, wherein the door body polymer includes a thermoplastic.

4. The container of claim 1, wherein the door body polymer includes at least one material selected from the group consisting of polycarbonate, cyclic olefin, liquid crystal polymer, polypropylene, polyphenylene sulfide (PPS), polyphenylene sulfone (PPSU), polyetherimides, polyimide, polyamide imide, polyketone, polyether sulfone (PES), polybutylene terephthalate, polysulfone (PSU, PSF), polyaryl ether ketone (PAEK), polyether ether ketone (PEEK), polyether ketone (PEKK) and polyether ketone ether ketone ketones (PEKEKK).

5. The container of claim 1, wherein the seal member is formed integrally with the door body by injection molding.

6. The container of claim 2, wherein the connection portion interlocks with the seal coupling portion of the door body.

7. The container of claim 6, wherein the connection portion of the seal member has an enlarged edge, the enlarged edge being configured to held by the seal coupling portion of the door body to form an interlocking connection, thereby preventing withdrawal of the connection portion from the seal coupling portion of the door body.

8. The container of claim 7, wherein the seal coupling portion includes a gap and a channel; when viewed in a cross section view, a width of gap of the seal coupling portion being smaller than a width of the channel.

9. The container of claim 8, wherein the connection portion includes a first polymer, the first polymer having a compressibility configured to prevent the enlarged edge of the connection portion from being compressed to a size equal to or smaller than the gap of the seal coupling portion formed into the door body so as to form the interlocking connection.

10. The container of claim 7, wherein the enlarged edge of the connection portion of the seal member is joined to and formed around by the seal coupling portion of the door body.

11. The container of claim 2, wherein the contact portion includes a wiper-type gasket.

12. The container of claim 2, wherein the connection portion is made of a first polymer different from the door body polymer.

13. The container of claim 12, wherein the first polymer includes polyether ether ketone, liquid crystal polymer, or a combination thereof.

14. The container of claim 12, wherein the contact portion is made of a second polymer different from the first polymer and the door body polymer.

15. The container of claim 14, wherein the second polymer includes an elastomeric polymer.

16. The container of claim 14, wherein the second polymer includes a thermoset or a thermoplastic elastomer.

17. The container of claim 14, wherein the second polymer includes a polymer that has a shore durometer not less than 30 shore.

18. The container of claim 14, wherein the second polymer is capable of withstanding a temperature of 130° C.

19. The container of claim 14, wherein the second polymer includes at least one material selected from the group consisting of fluoropolymer, fluoroelastomer (FKM), perfluoro elastomer (FKKM), styrenic block copolymer (SBC), polyether-ester block copolymer (COPE), thermoplastic olefin (TPO), thermoplastic vulcanizate (TPV), thermoplastic polyuerethane (TPU) and copolyamide elastomer (COPA).

20. The container of claim 14, wherein the first polymer has hardness and stiffness that are greater than those of the second polymer

21. The container of claim 14, wherein the first polymer is capable of withstanding any temperature for the second polymer.

22. The container of claim 2, wherein the connection portion and the contact portion are made of the same polymer.

23. The container of claim 1, wherein the container is one of a front opening unified pod, a reticle pod, and a semiconductor substrates shipping container.

24. The container of claim 1, wherein the seal coupling portion is located at a periphery of the door body.

25. The container of claim 1, wherein the seal coupling portion extends along an entire circumference of the periphery of the door body.

26. A method of making a door that closes an open end of a housing of a substrate or reticle container, comprising:
insert molding a polymeric seal member on a seal coupling portion of a door body so that the polymeric seal member is integrally formed with the door body.

27. The method of claim 26, wherein the polymeric seal member is joined to and formed into a seal coupling portion of a door body of the door so that the polymeric seal member and the periphery of the door body are connected with each other.

28. The method of claim 26, further comprising:
forming the seal member, including:
forming a connection portion of the polymeric seal member from a first polymer different from the door body polymer, the connection portion including an enlarged edge sized to be formed into the seal coupling portion of the door body; and
forming a contact portion of the polymeric seal member from a second polymer different from the door body polymer and the first polymer, the contact portion being configured to seal the open end of the housing of the container when the door is in a closed position.
